(19) United States
(12) Patent Application Publication
(10) Pub. No.: US 2025/0349370 A1
(43) Pub. Date: Nov. 13, 2025

(54) ADAPTIVE MEMORY DEVICE PARTITION CLOSURE

(71) Applicant: Micron Technology, Inc., Boise, ID (US)

(72) Inventors: Tingjun Xie, Milpitas, CA (US); Jiangli Zhu, San Jose, CA (US); Zhongguang Xu, San Jose, CA (US); Steven Michael Kientz, Westminster, CO (US); Yang Liu, Melissa, TX (US); Zhenlei Shen, Milpitas, CA (US)

(21) Appl. No.: 19/191,138

(22) Filed: Apr. 28, 2025

Related U.S. Application Data
(60) Provisional application No. 63/643,485, filed on May 7, 2024.

(51) Int. Cl. G11C 16/34; G11C 16/10

(52) U.S. Cl. CPC G11C 16/3418; G11C 16/102; G11C 16/3495

(57) ABSTRACT

Various aspects of the present disclosure relate to adaptive memory device partition closure. In some aspects, a memory device may open a partition comprising a plurality of sets of memory cells. The memory device may program one or more sets of memory cells of the plurality of sets of memory cells. The memory device may update, based on an aggregated drive temperature, an accumulated value that is reflective of one or more physical parameters of the one or more sets of memory cells. The memory device may determine whether the accumulated value satisfies a threshold criterion. The memory device, responsive to determining that the accumulated value satisfies the threshold criterion, may close the partition.

### REFERENCE TO RELATED APPLICATION

This application claims the priority benefit of U.S. Provisional Patent Application No. 63/643,485, filed May 7, 2024, the entirety of which is incorporated herein by reference.

### TECHNICAL FIELD

Aspects of the disclosure relate generally to memory sub-systems, and more specifically, relate to adaptive memory device partition closure.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various aspects of the disclosure. The drawings, however, should not be taken to limit the disclosure to the specific aspects, but are for explanation and understanding only.

FIG. 1 illustrates an example computing system that includes a memory sub-system, in accordance with some aspects of the present disclosure.

FIG. 2 schematically illustrates a temporal voltage shift caused by a slow charge loss exhibited by triple-level memory cells, in accordance with some aspects of the present disclosure.

FIG. 3 depicts an example graph illustrating a dependency of a threshold voltage offset on a time after program (e.g. a period of time elapsed since a block had been programmed), in accordance with some aspects of the present disclosure.

FIG. 4 schematically illustrates a set of predefined threshold voltage offset bins, in accordance with aspects of the present disclosure.

FIG. 5 schematically illustrates block family management operations implemented by a block family manager component operating in accordance with some aspects of the present disclosure.

FIG. 6 schematically illustrates selecting block families for calibration, in accordance with embodiments of the present disclosure.

FIG. 7 schematically illustrates example metadata maintained by the memory sub-system controller for associating block partitions with block families, in accordance with embodiments of the present disclosure.

FIG. 8 schematically illustrates example metadata maintained by the memory sub-system controller for associating block families with voltage offset bins and corresponding threshold voltage offsets, in accordance with embodiments of the present disclosure.

FIG. 9 is a flow diagram of an example method for adaptive memory device partition closure, in accordance with some aspects of the present disclosure.

FIG. 10 is a flow diagram of an example method for block family error avoidance partition management, in accordance with some aspects of the present disclosure.

FIG. 11 is a block diagram of an example computer system in which some aspects of the present disclosure may operate.

### DETAILED DESCRIPTION

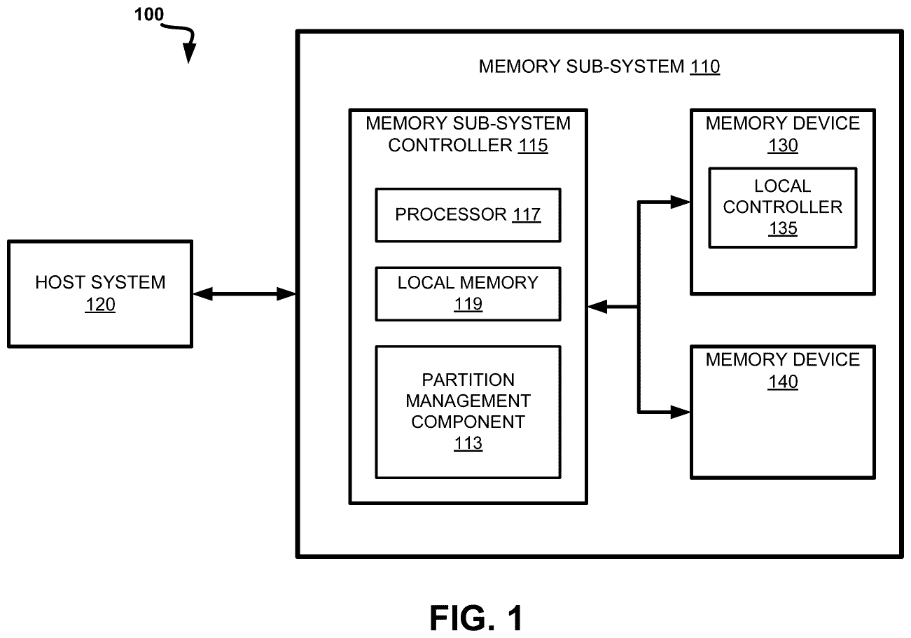

Aspects of the present disclosure are directed to adaptive memory device partition closure. A memory sub-system can be a storage device, a memory module, or a combination of a storage device and memory module. Examples of storage devices and memory modules are described below in conjunction with FIG. 1. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. One example of non-volatile memory devices is a not-and (NAND) memory device. Other examples of non-volatile memory devices are described below in conjunction with FIG. 1. A non-volatile memory device is a package of one or more dies. Each die can include one or more planes. For some types of non-volatile memory devices (e.g., NAND devices), each plane includes of a set of physical blocks. Each block includes of a set of pages. Each page includes of a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1”, or combinations of such values.

A memory device can include multiple memory cells arranged in a two-dimensional or a three-dimensional grid. Memory cells are formed onto a silicon wafer in a rectangular array; the memory cells may be joined by conductive lines referred to as wordlines and bitlines. The intersection of a bitline and wordline constitutes the address of the memory cell. A block hereinafter refers to a unit of the memory device used to store data and can include a group of memory cells, a wordline group, a wordline, or individual memory cells. One or more blocks can be grouped together to form separate partitions (e.g., planes) of the memory device in order to allow concurrent operations to take place on each plane. The memory device can include circuitry that performs concurrent memory page accesses of two or more memory planes. For example, the memory device can include multiple access line driver circuits and power circuits that can be shared by the planes of the memory device to facilitate concurrent access of pages of two or more memory planes, including different page types. For case of description, these circuits can be generally referred to as independent plane driver circuits. Depending on the storage architecture employed, data can be stored across the memory planes (i.e., in stripes). Accordingly, one request to read a segment of data (e.g., corresponding to one or more data addresses), can result in read operations performed on two or more of the memory planes of the memory device.

A block family refers to a set of blocks within a memory device that have similar characteristics, such as the same physical location, the same operating conditions, and/or the same performance attributes. For example, in NAND flash memory, blocks within a same physical region of a memory array may be grouped into a block family. A block family error may occur when one or more blocks within a block family experience faults or errors during operation. These faults or errors may arise due to various factors such as manufacturing defects, wear-out effects, or transient faults, among other examples. Block family errors may lead to data corruption within a memory device, loss of integrity for the memory device, or failure of the memory device to operate properly. Block family error avoidance (BFEA) refers to strategies and techniques that can be employed to minimize or mitigate the occurrence or impact of block family errors. BFEA techniques may enhance the reliability, longevity, and performance of the memory device, for example, by reducing a likelihood of block family error occurrence.

Slow charge loss (SCL) refers to the gradual dissipation of charge from memory cells over an extended period, such as over days, weeks, or months. Unlike rapid charge loss, which may occur due to sudden electrical or environmental stresses, SCL may be a subtle and persistent effect on the memory cells. SCL can be influenced by factors such as temperature, voltage levels, and overall usage patterns of the memory device. The rate of SCL may vary in accordance with the specific technology and design of the memory device and/or in accordance with environmental conditions. SCL may compromise the integrity of stored data stored in the memory device over time, potentially leading to bit errors and/or data corruption. In extreme cases, for example, if the charge loss exceeds a threshold that is required to maintain the integrity of stored data, SCL may result in complete data loss or unrecoverable errors. BFEA may be used to continuously the track the SCL of stored data over time and to select an appropriate read level offset when the written data is later retrieved (e.g., read).

Data may be written to the memory cells of a memory device in accordance with the physical and logical structure of the memory device. In some implementations, the memory device may be logically split into superblocks, such that each superblock includes a set of equally positioned blocks spanning over multiple dies of the memory device (for example, a first superblock may include a first block of each die and a second superblock may include a second block of each die). In turn, each block includes a set of pages. In some cases, BFEA may include the tracking of blocks or pages that have been programmed within the same window of a predefined duration (e.g., one hour) to form a block family. This may enable an operating system of the memory device to more efficiently manage available space, distribute wear leveling, and reduce overhead associated with tracking the wear status of individual blocks.

A memory device controller may continuously measure and track the SCL of one or more partitions on the drive. In some cases, it may be necessary to limit the number of partitions that are allowed on the drive, for example, due to the size of the block family metadata and/or management overhead. For example, each superblock may allow a maximum of four partitions, and each partition may be force closed every hour. Limiting the number of partitions on the drive may result in open blocks (OBs) being converted to partial blocks (PBs), which may be an inefficient utilization of the memory device blocks. For example, forcing the OBs to be converted to PBs may cause unnecessary erase pool size reductions and/or may result in an increased folding rate and write amplification on the drive. Additionally, a large quantity of unnecessary PBs on the drive may increase firmware handling overhead and complexity, which may reduce a performance capability of the drive. Further, limiting the number of partitions on the drive may result in long term degradation of the memory device program/erase count (PEC) budget and/or may reduce potential sequential drive writes per day (SDWPD), random drive writes per day (RDWPD), and total bytes written (TDW) goals.

Aspects of the present disclosure address the above and other deficiencies by having a memory device that performs adaptive memory device partition closure. In some aspects, the memory device may open a partition that includes multiple sets of memory cells. The partition may be a BFEA partition that includes multiple full or partial blocks that have been written within a certain time duration and that share one or more similar characteristics (such as the same SCL). The memory device may program one or more sets of memory cells of the multiple sets of memory cells. For example, the memory device may program the one or more sets of memory cells by writing data across one or more pages of a superblock associated with the BFEA partition. In some aspects, the memory device may determine whether a data retention threshold associated with the BFEA partition has been satisfied and may close the BFEA partition based on determining that the data retention threshold has been satisfied. For example, if the memory device determines that the BFEA partition has been open for a time period that is longer than a time period indicated by the data retention threshold, the memory device may close the BFEA partition.

The memory device may update an accumulated value that is reflective of one or more physical parameters of one or more memory cells associated with the superblock. The one or more physical parameters may be (or may include) an SCL of the one or more memory cells associated with the superblock. The memory device may update the accumulated value based on an aggregated drive temperature. For example, the memory device, to update the accumulated value, may calculate, for each iteration of a recurring time interval, an average drive temperature using one or more drive temperature values that are sampled during the iteration of the recurring time interval, may calculate, for each average drive temperature of multiple average drive temperatures, an equivalent value (for example, an equivalent SCL value) that is based on a baseline temperature value, and may add the equivalent value to one or more previous equivalent values associated, respectively, with one or more previous iterations of the recurring time interval. Therefore, the accumulated value may be a sum of multiple equivalent values, where each equivalent value of the multiple equivalent values is based on an average aggregated drive temperature that is associated with an iteration of a recurring time interval. The memory device may compare the accumulated value to a threshold criterion and may determine whether the accumulated value satisfies (e.g., exceeds) the threshold criterion. If the memory device determines that the accumulated value satisfies the threshold, the memory device may close the BFEA partition. Otherwise, the memory device may perform another iteration of updating the accumulated value and comparing the accumulated value to the threshold criterion.

In some aspects, the partition may include multiple dies on the drive. Due to die-to-die variations on the drive, the memory device may track each die temperature separately. For example, the memory device may obtain an accumulated value for each die associated with the partition and may compare each accumulated value to the threshold criterion. The memory device may determine to close the partition if the accumulated value associated with a single die satisfies the threshold criterion, regardless of whether the accumulated values of the other dies satisfy the threshold criterion.

Some advantages of the present disclosure may include improving SCL management for superblock partitions of a memory device. Some advantages of the present disclosure may include reducing unnecessary partition closures and quantities of closed partial blocks under certain host workloads. Some advantages of the present disclosure may include improving folding rate and write amplification profiles on the drive, which may result in an increased performance of the drive. Some advantages of the present disclosure may include increasing a memory device PEC budget and increasing an achievable SDWPD, RDWPD, or TBW on the drive. Some other advantages of the present disclosure may be described below.

FIG. 1 illustrates an example computing system 100 that includes a memory sub-system 110 in accordance with some aspects of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some aspects, the host system 120 is coupled to multiple memory sub-systems 110 of different types. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the physical host interface (e.g., PCIe or CXL bus). The physical host interface can provide an interface for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a not-and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SCL) can store one bit per cell. Other types of memory cells, such as multi-level cells (MLCs), triple level cells (TLCs), quad-level cells (QLCs), and penta-level cells (PLCs) can store multiple bits per cell. In some aspects, each of the memory devices 130 can include one or more arrays of memory cells such as SCLs, MLCs, TLCs, QLCs, PLCs or any combination of such. In some aspects, a particular memory device can include an SCL portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), not-or (NOR) flash memory, or electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some aspects, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some aspects, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some aspects, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some aspects, memory sub-system 110 is a managed memory device, which is a raw memory device 130 having control logic (e.g., local media controller 135) on the die and a controller (e.g., memory sub-system controller 115) for media management within the same memory device package. An example of a managed memory device is a managed NAND (MNAND) device.

The memory sub-system 110 includes a partition management component 113 that can perform adaptive memory device partition closure. In some aspects, the memory sub-system controller 115 includes at least a portion of the partition management component 113. In some aspects, the partition management component 113 is part of the host system 120, an application, or an operating system. In other aspects, local media controller 135 includes at least a portion of partition management component 113 and is configured to perform the functionality described herein.

In some aspects, the partition management component 113 included in the memory sub-system controller 115 may open a partition for one or more active cursors. A cursor may be a pointer or index that is used, for example, to track the memory device location where the data is to be written. The partition management component 113 may identify one or more active cursors (such as cursors that are currently in use or that are needed for a particular operation) and may open a partition (such as a BFEA partition) for the one or more cursors. After opening the one or more partitions, the partition management component 113 may program host data into the partition. For example, the partition management component 113 may write data from the host system 120 into a partition associated with the cursor.

In some aspects, the partition management component 113 may compare a time period during which the partition has been open to a time period associated with data retention threshold. If the partition management component 113 determines that the partition has been open for a time period that is longer than the time period associated with the data retention threshold, the partition management component 113 may close the BFEA partition. Alternatively, if the partition management component 113 determines that the partition has not been open for the time period that is longer than the time period associated with the data retention threshold, the partition management component 113 may update an accumulated value that is based on an aggregated drive temperature and that is reflective of one or more physical parameters (for example, an SCL parameter) of the one or more memory cells. In some aspects, the accumulated value may be a sum of multiple equivalent values, where each equivalent value of the multiple equivalent values is based on an average aggregated drive temperature that is associated with an iteration of a recurring time interval. The partition management component 113 may compare the accumulated value to a threshold criterion and may determine whether the accumulated value exceeds the threshold criterion. If the partition management component 113 determines that the accumulated value exceeds the threshold, the partition management component 113 may close the BFEA partition. Otherwise, the partition management component 113 may perform another iteration of updating the accumulated value and comparing the accumulated value to the threshold criterion.

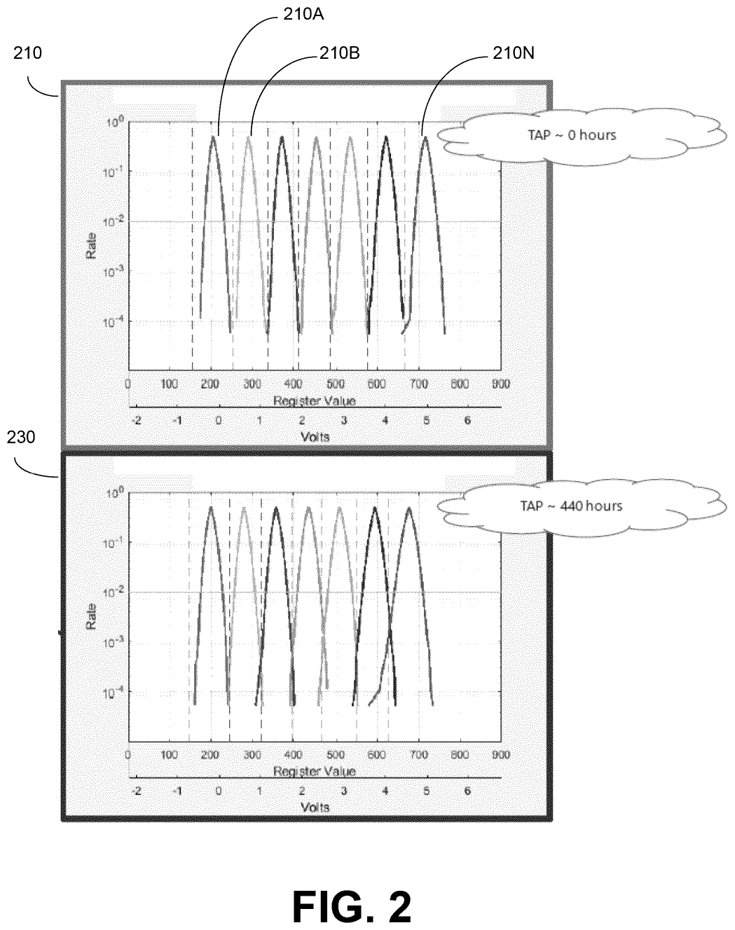

FIG. 2 schematically illustrates a temporal voltage shift caused by a slow charge loss exhibited by triple-level memory cells. While the illustrative example of FIG. 2 utilizes triple-level cells, the same observations can be made and, accordingly, the same remedial measures are applicable to single level cells and multi-level cells in order to compensate for the slow charge loss.

As noted herein above, a memory cell can be programmed (written to) by applying a certain voltage to the memory cell, which results in an electric charge being held by the memory cell, thus allowing modulation of the voltage distributions produced by the memory cell. Precisely controlling the amount of the electric charge stored by the memory cell allows to establish multiple threshold voltage levels corresponding to different logical levels, thus effectively allowing a single memory cell to store multiple bits of information: a memory cell operated with 2ⁿ different threshold voltage levels is capable of storing n bits of information.

In FIG. 2, each graph 220A-220N shows a voltage distribution produced by memory cells programmed by a respective write level (which can be assumed to be at the midpoint of the distribution) to encode a corresponding logical level (“000” through “111” in case of a TLC). In order to distinguish between neighboring distributions (corresponding to two different logical levels), the threshold voltage levels (shown by dashed vertical lines) are defined, such that any measured voltage that falls below a threshold level is associated with one distribution of the pair of neighboring distributions, while any measured voltage that is greater than or equal to the threshold level is associated with another distribution of the pair of neighboring distributions.

As seen from comparing example charts 210 and 230, which reflect the time periods immediately after programming and 440 hours after programming, respectively, the voltage distributions change in time due to the slow charge loss, which results in drifting values of the threshold voltage levels, which are shown by dashed vertical lines. In various aspects of the present disclosure, the temporal voltage shift is selectively tracked for programmed blocks grouped by block families, and appropriate voltage offsets, which are based on block affiliation with a certain block family, are applied to the base read levels in order to perform read operations.

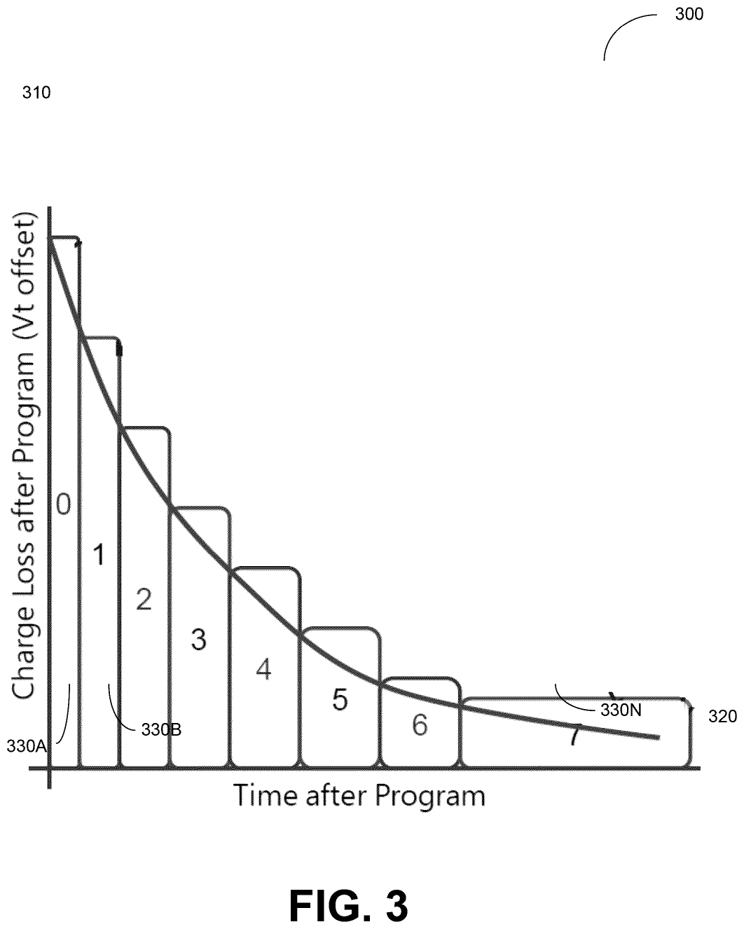

FIG. 3 depicts an example graph 300 illustrating the dependency of the threshold voltage offset 310 on the time after program 320 (i.e., the period of time elapsed since the block had been programmed. As schematically illustrated by FIG. 3, blocks of the memory device are grouped into block families 330A-330N, such that each block family includes one or more full or partial blocks that have been programmed within a specified time window and a specified temperature window. As noted herein above, since the time elapsed after programming and temperature are the main factors affecting the temporal voltage shift, all blocks and/or partitions within a single block family 310 are presumed to exhibit similar distributions of threshold voltages in memory cells, and thus would require the same voltage offsets for read operations.

Block families can be created asynchronously with respect to block programming events. In an illustrative example, the memory sub-system controller 115 of Fig. I can create a new block family whenever a specified period of time (e.g., a predetermined number of minutes) has elapsed since creation of the last block family or whenever the reference temperature of memory cells, which is updated at specified time intervals, has changed by more than a specified threshold criterion since creation of the current block family.

A newly created block family can be associated with bin 0. Then, the memory sub-system controller can periodically perform a calibration process in order to associate each die of every block family with one of the predefines threshold voltage offset bins (bins 0-7 in the illustrative example of FIG. 3), which is in turn associated with the voltage offset to be applied for read operations. The associations of blocks with block families and block families and dies with threshold voltage offset bins can be stored in respective metadata tables maintained by the memory sub-system controller.

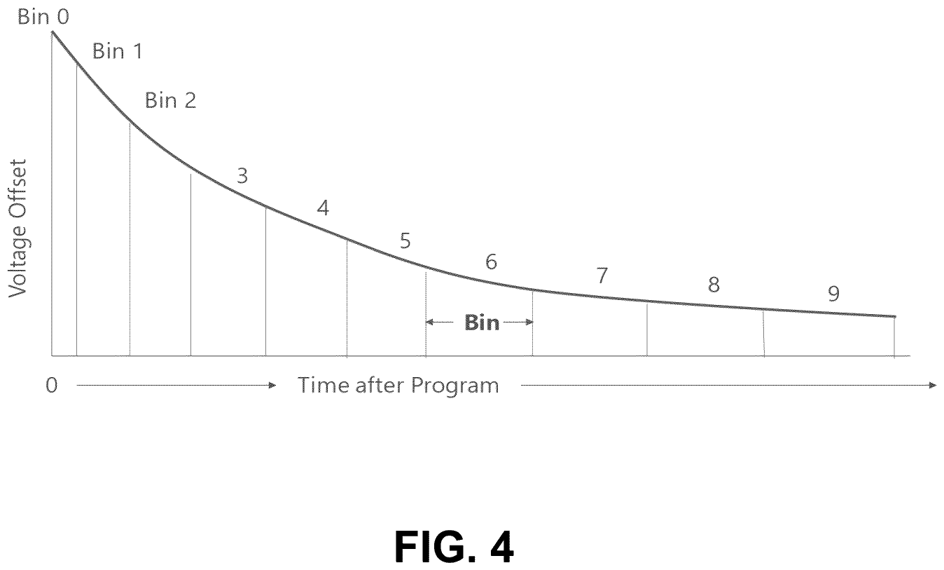

FIG. 4 schematically illustrates a set of predefined threshold voltage offset bins (bin 0 to bin 9), in accordance with aspects of the present disclosure. As schematically illustrated by FIG. 4, the threshold voltage offset graph can be subdivided into multiple threshold voltage offset bins, such that each bin corresponds to a predetermined range of threshold voltage offsets. While the illustrative example of FIG. 4 defines ten bins, in other aspects, various other numbers of bins can be employed (e.g., 64 bins). Based on a periodically performed calibration process, the memory sub-system controller associates each die of every block family with a threshold voltage offset bin, which defines a set of threshold voltage offsets to be applied to the base voltage read level in order to perform read operations, as described in more detail herein below.

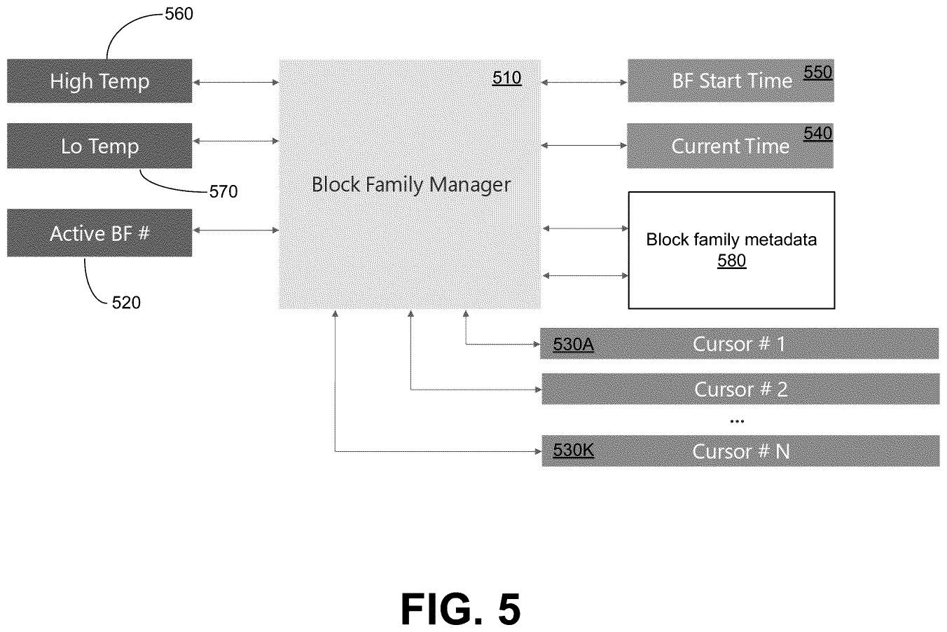

FIG. 5 schematically illustrates block family management operations implemented by a block family manager component of the memory-sub-system controller operating in accordance with aspects of the present disclosure. As schematically illustrated by FIG. 5, the block family manager 510 can maintain, in a memory variable, an identifier 520 of the active block family, which is associated with one or more blocks of cursors 530A-530K as they are being programmed. “Cursor” herein shall broadly refer to a location on the memory device to which the data is being written.

The memory sub-system controller can utilize a power on minutes (POM) clock for tracking the creation times of block families. In some aspects, a less accurate clock, which continues running when the controller is in various low-power states, can be utilized in addition to the POM clock, such that the POM clock is updated based on the less accurate clock upon the controller wake-up from the low-power state.

Thus, upon initialization of each block family, the current time 540 is stored in a memory variable as the block family start time 550. As the blocks are programmed, the current time 540 is compared to the block family start time 550. Responsive to detecting that the difference of the current time 540 and the block family start time 550 is greater than or equal to the specified time period (e.g., a predetermined number of minutes), the memory variable storing the active block family identifier 520 is updated to store the next block family number (e.g., the next sequential integer number), and the memory variable storing the block family start time 550 is updated to store the current time 540.

The block family manager 510 can also maintain two memory variables for storing the high and low reference temperatures of a selected die of each memory device. Upon initialization of each block family, the high temperature 560 and the low temperature 570 variable store the value of the current temperature of the selected die of the memory device. In operation, while the active block family identifier 520 remains the same, temperature measurements are periodically obtained and compared with the stored high temperature 560 and the low temperature 570 values, which are updated accordingly: should the temperature measurement be found to be greater than or equal to the value stored by the high temperature variable 560, the latter is updated to store that temperature measurement; conversely, should the temperature measurement be found to fall below the value stored by the low temperature variable 570, the latter is updated to store that temperature measurement.

The block family manager 510 can further periodically compute the difference between the high temperature 560 and the low temperature 570. Responsive to determining that the difference between the high temperature 560 and the low temperature 570 is greater than or equal to a specified temperature threshold, the block family manager 510 can create a new active block family: the memory variable storing the active block family identifier 520 is updated to store the next block family number (e.g., the next sequential integer number), the memory variable storing the block family start time 550 is updated to store the current time 540, and the high temperature 560 and the low temperature 570 variables are updated to store the value of the current temperature of the selected die of the memory device.

In some examples, the block family manager 510 can periodically measure a drive temperature on a drive that includes the block family. If the drive temperature is higher than the high temperature 560, the block family manager 510 can close a partition associated with the block family. Alternatively, if the drive temperature is lower than the high temperature 560 (for example, is between the high temperature 560 and the low temperature 570), the block family manager 510 can compute an accumulated value that is based on the drive temperature and one or more previous drive temperatures. In some examples, the block family manager 510 may close the partition based on determining that the accumulated value is higher than a threshold criterion.

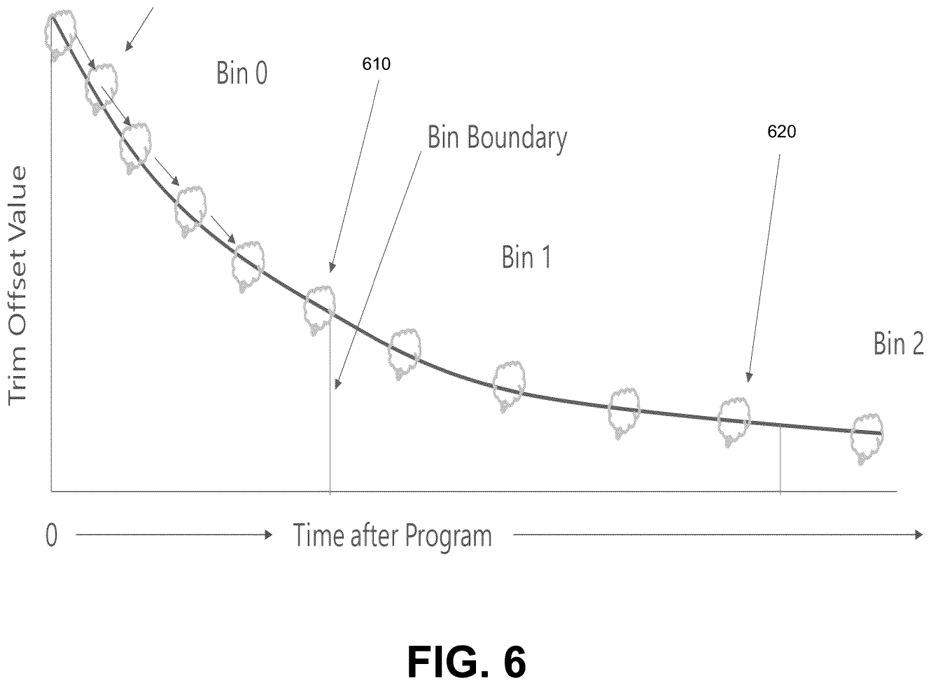

At the time of programming a full or partial block, the memory sub-system controller associates the block (or its partition) with the currently active block family. In an illustrative example, since the programming is done on the page level, one subset of pages (partition) of a block can be programmed within a time period associated with one block family, while the next partition of the block can be programmed within the next time period, which is associated with another block family, etc. Accordingly, the association of each full or partial block with a corresponding block family is reflected by the block family metadata 580, which can be represented by a combination of a block family table and a linked list of groups, as described in more detail herein below with reference to FIGS. 6-8.

FIG. 6 schematically illustrates selecting block families for calibration, in accordance with embodiments of the present disclosure. As schematically illustrated by FIG. 6, the memory sub-system controller can limit the calibration operations to the oldest block family in each bin (e.g., block family 610 in bin 0 and block family 620 in bin 1), since it is the oldest block family that will, due to the slow charge loss, migrate to the next bin before any other block family of the current bin.

As noted herein above, the association of each full or partial block with a corresponding block family is reflected by the block family metadata, which can be represented by a combination of a block family table and a linked list of partition groups, which can be utilized for identifying, for a given page or set of pages, the associated block family and the corresponding threshold voltage offset bin for performing a read operation.

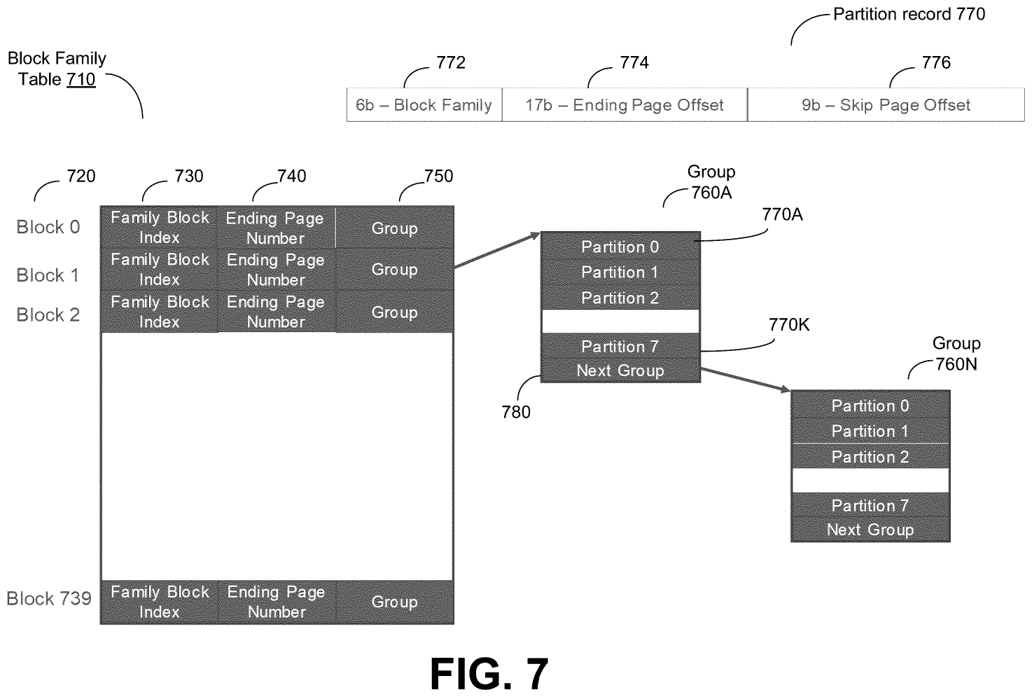

FIG. 7 schematically illustrates example metadata maintained by the memory sub-system controller for associating block partitions with block families, in accordance with embodiments of the present disclosure. As schematically illustrated by FIG. 7, the memory sub-system controller can maintain the block family table 710, which is indexed by the block number 720. Each record of the block family table 710 specifies, for the block referenced by the index of the record, an identifier 730 of the block family associated with the continuous set of pages of the block, in which the page number does not exceed the ending page number 740 specified by the record. In other words, i-th record of the block family table 710 maps at least a subset of pages of the i-th block to the block family 730 specified by the i-th record, such that the subset of pages includes the pages having their respective page numbers from 0 to the ending page number 740 specified by the i-th record.

The null value of the group field 750 indicates that no more partitions are currently associated with the block. Unless ending page number 740 specifies the last page of the block (i.e., the ending page number is equal to the number of pages in the block minus one), the flash translation layer may, upon programming the next subset of pages of the block, associate those pages with the then current block family, and reflect the association by creating a new partition (which would involve creating the first partition group 760A).

As noted herein above, since the programming is done on the page level, the first subset of pages (partition) of a block can be programmed within a time period associated with one block family, while the next partition of the block can be programmed within the next time period, which is associated with another block family, etc. Accordingly, the remaining pages of the i-th block (i.e., the pages having the page numbers exceeding the value specified by the ending page number 740) can be split into one or more continuous sets of pages (partitions), such that each partition including one or more pages is associated with a respective block family.

The partitions of a given block (except for the first partition starting at page number 0 including ending page number—1 pages) are grouped into partition groups 760A-760N, which are organized in a linked list, such that the first group of partitions 760A of a given block is referenced by the group filed 750 of the block family table 710, and each group of partitions (e.g., group 760A) references the next group of partitions (e.g., group 760N) associated with the given block.

Each group 760 includes up to a predetermined number (e.g., seven) of partitions 770A-770K. For each partition 770, the group table 760 specifies its block family association 772, its ending page offset 774, and the skip page offset 776 for implementing the binary search within the group.

Each partition record 770 record of the group table 760 specifies, for the partition referenced by the index of the record, an identifier 772 of the block family associated with the partition, and the ending page number 774 of the partition. In other words, each record of the group table 760 maps a corresponding partition to the block family 772 specified by the record, such that the partition includes the pages which have the numbers from the ending page of the previous partition to the ending page of the current partition minus one.

The null value of the next group field 770 indicates that no more partitions are currently associated with the block. Unless ending page number 776 of the last partition of the current partition group 760A specifies the last page of the block (i.e., the ending page number is equal to the number of pages in the block minus one), the flash translation layer may, upon programming the next subset of pages of the block, associate those pages with the then current block family, and reflect the association by creating a new partition (which would involve creating a new partition group 760N and linking it to the current partition group 760A by setting the next group field 770 of the current partition group 760A to point to the next partition group 760N).

The skip page offset field 776 specifies the offset to be added to the ending page number 774 in order to determine the page number corresponding to the midpoint of the remaining partitions of the group, thus allowing implementing of a binary search within the group. Accordingly, the computation complexity of searching a given page number within a group would not exceed ceil(log₂(M)), where M specifies the number of partitions within a single group 760 and ceil(x) is a function that returns the smallest integer that is equal to or exceeds its argument x. In the illustrative example of FIG. 7 the number of partitions within a group is 7, and thus the computation complexity of searching a given page number within a group would not exceed ceil(log₂7)=3.

The correct group can be identified by walking the linked list of groups, starting with the first group. If the specified page number is less than or equal to the ending page number of the group, the current group is searched for identifying the partition which includes the specified page number. Otherwise, should the specified page number exceed the ending page number, the next group (identified by field 780 of the group table 760) is searched. As identifying the group requires a linked list walk, the overall computational complexity of identifying the block family corresponding to a given page number is a linear function of the number of groups.

As noted herein above, upon identifying the block family associated with a given page or set of pages, the memory sub-system controller can identify the threshold voltage offset bin associated with the block family and die on which the block resides, compute the new threshold voltage by additively applying the threshold voltage offset associated with the threshold voltage offset bin to the base read level, and perform the read operation using the new threshold voltage.

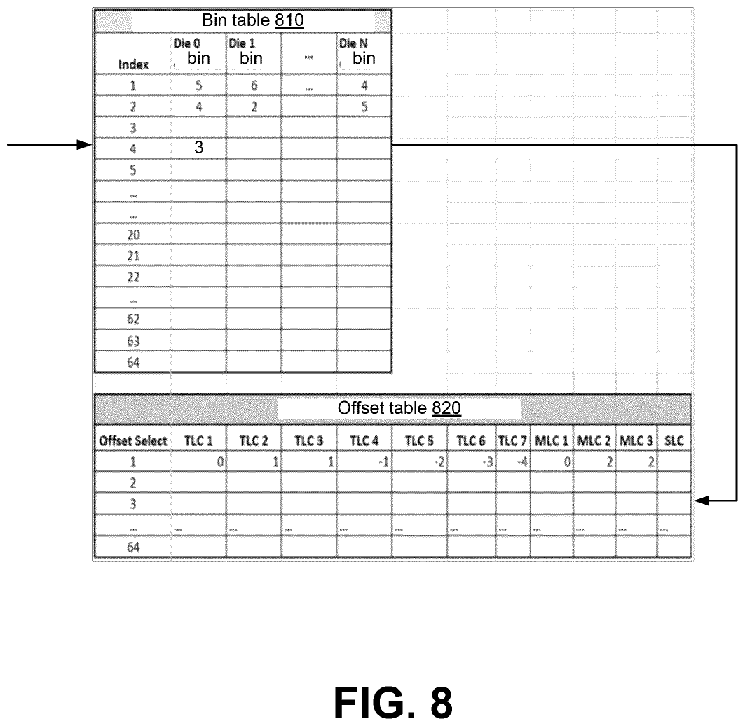

FIG. 8 schematically illustrates example metadata maintained by the memory sub-system controller for associating block families with voltage offset bins and corresponding threshold voltage offsets, in accordance with embodiments of the present disclosure. As schematically illustrated by FIG. 8, the memory sub-system controller can maintain the bin table 810 and the offset table 820.

The bin table 810 is indexed by the block family number, such that each record of the bin table 810 specifies, for the block family referenced by the index of the record, a set of threshold voltage offset bins associated with respective dies of the block family. In other words, each record of the bin table 810 includes a vector, each element of which specifies the threshold voltage offset bin associated with the die referenced by the index of the vector element. The threshold voltage offset bins to be associated with the block family dies can be determined by the calibration process, as described in more detail herein above.

Finally, the offset table 820 is indexed by the bin number. Each record of the offset table 820 specifies a set of threshold voltage offsets (e.g., for TLC, MLC, and/or SCL) associated with threshold voltage offset bin.

The metadata tables 710, 769, 810, and 820 can be stored on one or more memory devices 130 of FIG. 1. In some implementations, at least part of the metadata tables can be cached in the local memory 119 of the memory sub-system controller 115 of FIG. 1.

In operation, upon receiving a read command, the memory sub-system controller determines the physical address corresponding to the logical block address (LBA) specified by the read command. Components of the physical address, such as the physical block number, page number and the die identifier, are utilized for performing the metadata table walk: first, the block family table 710 and group tables 760A-760N is used to identify the block family identifier corresponding to the physical block number and the page number. Then, the block family identifier is used as the index to the bin table 810 in order to determine the threshold voltage offset bin associated with the block family and the die; finally, the identified threshold voltage offset bin is used as the index to the offset table 820 in order to determine the threshold voltage offset corresponding to the bin. The memory sub-system controller can then additively apply the identified threshold voltage offset to the base voltage read level in order to perform the requested read operation.

In the illustrative example of FIG. 8, the block family 4 is utilized as the index to the family table 820 in order to determine that die 0 is mapped to bin 3. The latter value is used as the index to the offset table in order to determine the threshold voltage offset values for bin 3.

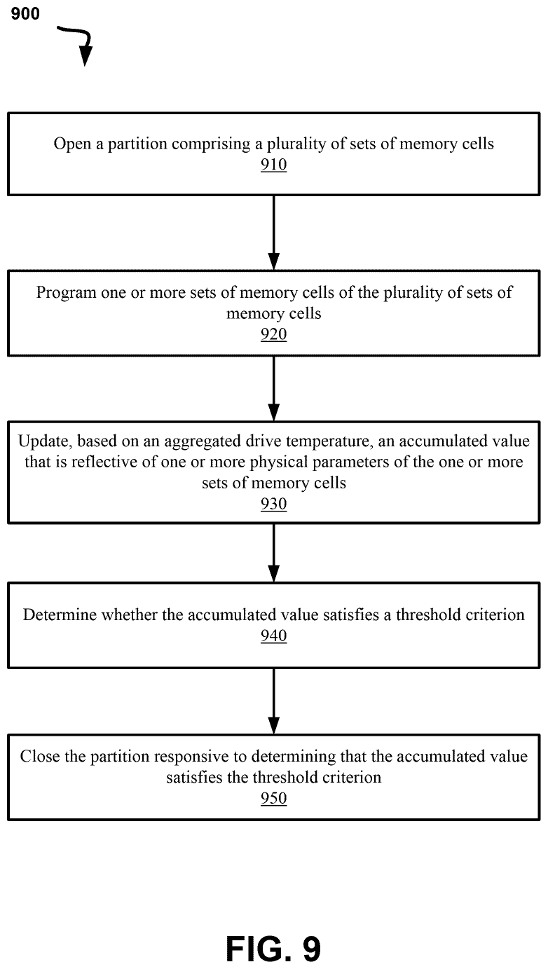

FIG. 9 is a flow diagram of an example method 900 for adaptive memory device partition closure, in accordance with some aspects of the present disclosure. The method 900 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some aspects, the method 900 is performed by the partition management component 113 of FIG. 1. Although shown in a particular sequence or order, unless otherwise specified, the order of the processes can be modified. Thus, the illustrated aspects should be understood only as examples, and the illustrated processes can be performed in a different order, and some processes can be performed in parallel. Additionally, one or more processes can be omitted in various aspects. Thus, not all processes are required in every embodiment. Other process flows are possible.

At operation 910, the processing logic opens a partition. The partition may be a BFEA partition that includes a plurality of sets of memory cells (e.g., a subset of pages of a superblock). The processing logic may open the partition in accordance with one or more conditions. For example, the processing logic may open the partition based on data being written to one or more memory cells of the memory device within a certain time duration (e.g., one hour). The processing logic may determine that data written to the one or more memory cells within the certain time duration is to be treated as a group, and therefore, may logically mark (e.g., tag) the data as being associated with the partition. In some aspects, data that is included within the same partition may have the same physical characteristics. For example, data that is included within the same partition may have the same SCL.

At operation 920, the processing logic programs one or more sets of memory cells of the plurality of sets of memory cells. In some aspects, programming the one or more sets of memory cells may include writing to one or more pages of a superblock. As described herein, the superblock may include a set of equally positioned blocks that span over multiple dies of the memory device. For example, a first superblock may include a first block of each die and a second superblock may include a second block of each die. In some aspects, the partition may contain an entirety of the superblock. In some other aspects, the partition may contain one or more wear levels (WLs) of the superblock that amount to less than the entirety of the superblock.

At operation 930, the processing logic updates, based on an aggregated drive temperature, an accumulated value that is reflective of one or more physical parameters of the one or more memory cells. The one or more physical parameters of the one or more memory cells may be (or may include) an SCL of the one or more memory cells. The aggregated drive temperature may be based on a sum of multiple average temperature values that are obtained at various intervals after the superblock is opened.

In some aspects, the processing logic may determine that each partition can tolerate a certain amount of SCL dispersion. The amount of SCL dispersion that can be tolerated by each partition may be based, for example, on a trigger rate specification associated with the memory device. The SCL dispersion may be expressed in terms of a data retention value (DR) and a temperature value (TEMP) (DR/TEMP). In one example, the SCL dispersion may be one hour over 85 degrees Celsius (85° C.) (1 hour/85° C.).

In some aspects, the memory device, to update the accumulated value, may calculate, for each iteration of a recurring time interval, an average drive temperature using one or more drive temperature values that are sampled during the iteration of the recurring time interval, may calculate, for each average drive temperature of multiple average drive temperatures, an equivalent value (for example, an equivalent SCL value) that is based on a baseline temperature value, and may add the equivalent value to one or more previous equivalent values associated, respectively, with one or more previous iterations of the recurring time interval. Therefore, the accumulated value may be a sum of multiple equivalent values, where each equivalent value of the multiple equivalent values is based on an average aggregated drive temperature that is associated with an iteration of a recurring time interval.

The processing logic may sample the drive temperature. In some aspects, the processing logic may sample the drive temperature using an interval δ. For example, the processing logic may sample the drive temperature every δ seconds to obtain the one or more drive temperature values. The interval δ may be selected to be large enough such that a frequency of the temperature samplings does not negatively impact the drive resources or bandwidth, and to be small enough such that drive temperature fluctuations are able to be accurately tracked. In some examples, δ can be tens or hundreds of milliseconds. A smaller Δ may result in a more accurate result, but may be dependent on drive resources, bandwidth limitations, and firmware overhead. A smaller Δ (such as Δ=δ/60 minutes) may or may not be feasible for a certain SSD depending, for example, on one or more characteristics of the SSD. In some examples, Δ can be equal to δ·10 or δ·100.

In some aspects, the processing logic may sample the drive temperature based on an occurrence of a triggering event. In some examples, the triggering event may be based on the sample period δ. For example, if δ=500 milliseconds, the firmware may automatically trigger a temperature measure event for measuring the drive temperature every 500 milliseconds. In some other examples, the triggering event may be based on an occurrence of a media management event or a drive temperature surge event, among other examples. The processing logic may calculate an average drive temperature Tₐ. In some aspects, the processing logic may calculate the average drive temperature Tₐ using another interval Δ. For example, the processing logic may calculate the average drive temperature Tₐ every Δ minutes based on the one or more drive temperature values that are sampled every δ seconds. If the processing logic (e.g., firmware) has sufficient bandwidth, Δ can be made as small as Δ=δ/60 minutes for improved SCL tracking accuracy. In some other aspects, the processing logic may sample the drive temperature based on an occurrence of a triggering event (for example, the same triggering event used for sampling the drive temperature, or a different triggering event).

The processing logic may calculate an equivalent value using the interval Δ. For example, every Δ minutes, the processing logic may calculate an equivalent SCL value under a baseline temperature and based on multiplying Tₐ and Δ. In some aspects, the processing logic may calculate the equivalent value using a formula, such as a thermal acceleration formula. Using the thermal acceleration formula, the processing logic may calculate an acceleration factor (AF) based on an activation energy (ΔH), a constant (k) (which may be Boltzmann's constant), a first temperature (T1) (which may be a previous drive temperature) and a second temperature (T2) (which may be a current drive temperature), where T1 and T2 are measured in degrees Kelvin. In some aspects, the processing logic may calculate an exponential function of an expression, where the expression includes a product of a first result and a second result, where the first result is obtained based on dividing the activation energy by the constant and the second result is obtained based on subtracting one divided the first temperature by one divided by the second temperature. For example, the processing logic may use the thermal acceleration formula to perform the following calculation:

$$AF = exp [ \frac{Δ H}{k} ( \frac{1}{{T}_{1}} - \frac{1}{{T}_{2}} ) ] .$$

The processing logic, using the above formula, may calculate the equivalent value (e.g., the equivalent SCL value) at multiple iterations of the interval Δ. In one example, the processing logic may determine that, for a first temperature value (TI), the equivalent value is equal to α1. The calculation may be performed on-the-fly or may be performed in an offline state. The equivalent value may indicate an effect on the memory cells of the memory device (for example, an SCL and/or other thermal effects) under certain temperatures. For example, a memory device operating at a higher temperature for one hour may experience greater SCL (and/or other thermal effects) than a memory device operating at a lower temperature for one hour. Therefore, the equivalent values may be used to indicate equivalent SCL (and/or other thermal effects) at various operating temperatures of the memory device. The processing logic may calculate the equivalent values using the formula and based on the first temperature value and/or the first equivalent value. In some aspects, the processing logic may determine that, for a second temperature value (T2), a third temperature value (T3), and a fourth temperature value (T4), the equivalent values are α2, α3, and α4, respectively. The calculation may be performed on-the-fly or may be performed in an offline state. The equivalent values may be stored in a Table (such as a look-up table (LUT)) as shown in Table 1.

TABLE 1
LUT Value

Temperature (T) (in Celsius)

| | T1 | T2 | T3 | T4 |
|---|---|---|---|---|
| Equivalent | α1 | α2 | α3 | α4 |
| value (α) | | | | |

As described herein, the processing logic may update the accumulated value based on the aggregated drive temperature, where updating the accumulated value based on the aggregated drive temperature includes updating the accumulated value based on multiple equivalent values that correspond to multiple drive temperature values associated with the aggregated drive temperature. In one example, the programming logic may determine that, during one iteration of the time interval Δ, the average drive temperature is equal to T3. Therefore, the accumulated value after the iteration of the time interval may be equal to the equivalent value α3·Δ. The programming logic may determine that, during a subsequent iteration of the time interval Δ, the average drive temperature is equal to T2. Therefore, the accumulated value after the subsequent time interval may be equal to the sum of the equivalent values (α3·Δ)+(α2·Δ). The programming logic may determine that, during another subsequent iteration of the time interval Δ, the average drive temperature is equal to T4. Therefore, the accumulated value after the other subsequent time interval may be equal to the sum of the equivalent values (α3·Δ)+(α2·Δ)+(α4+Δ).

At operation 940, the processing logic determines whether the accumulated value satisfies a threshold criterion. The processing logic may compare the accumulated value to the threshold criterion to determine whether the accumulated value satisfies the threshold criterion. In some aspects, the threshold criterion may be (or may indicate) an allowable SCL dispersion amount. Additionally, or alternatively, the threshold criterion may be based on a PEC of the drive.

At operation 950, the processing logic closes the partition responsive to determining that the accumulated value satisfies the threshold criterion. Closing the partition may include preventing any additional write operations (and/or other memory operations) from being performed within the partition. Otherwise, the processing logic may continue to allow write operations (and/or other memory operations) to be performed within the partition. Using the example above, after the first iteration of the time interval, the processing logic may determine that the accumulated value does not satisfy the threshold criterion and may continue to allow write operations to be performed within the partition. After the second iteration of the time interval, the processing logic may determine that the accumulated value does not satisfy the threshold criterion and may continue to allow write operations to be performed within the partition. After the third iteration of the time interval, the processing logic may determine that the accumulated value satisfies the threshold criterion. Therefore, the processing logic may close the partition.

In some aspects, the processing logic may close the partition using a straightforward approach. Using the straightforward approach, the processing logic may close the partition in accordance with determining that the accumulated value satisfies (e.g., exceeds) the threshold criterion (as described in the example above). Therefore, at any checkpoint, the processing device may close the partition if the accumulated value is higher than the threshold criterion.

In some other aspects, the processing logic may close the partition using a look-ahead approach. Using the look-ahead approach, the processing logic may close the partition in accordance with the accumulated value, associated with a current iteration of the recurring time interval, and a worst-case predicted value, associated with a subsequent iteration of the recurring time interval, satisfying (e.g., exceeding) the threshold criterion. The worst-case predicted value may correspond to the highest possible equivalent value (for example, from the LUT) for a subsequent time interval. The worst-case predicted value may be based on a highest predicted operating temperature of the partition at the subsequent time interval, and therefore, may indicate a highest predicted SCL of the partition at the subsequent time interval. Using the worst-case predicted approach may include calculating a sum of the accumulated value and a “predicted” equivalent value for the highest operating temperature of the memory cells included in the partition. Using the example above, the look-ahead approach may cause the processing logic to close the partition after the worst-case predicted is equal to α3·Δ+(α2·Δ) (with the assumption that α2 is the worse-case condition in the LUT), which is higher than the threshold criterion.

In some aspects, the processing logic may close the partition based on a data retention threshold. The data retention threshold may indicate a time period after which the processing logic is to close the partition regardless of whether accumulated value satisfies the threshold. For example, the processing logic may close the partition 24 hours after the partition has been opened or 36 hours after the partition has been opened, regardless of the drive temperature values. Closing the partition after an expiration of the data retention threshold may minimize media degradation caused by room temperature data retention (RTDR), among other examples.

As described herein, SCL is a function of time and temperature. For example, memory cells experiencing a lower temperature may be able to operate for a longer time period without significant SCL, whereas memory cells experiencing a higher temperature may be subject to SCL in a shorter time period. In some aspects, an intrinsic capability of the memory device (NAND) may guarantee that a single read level offset is sufficient for the partition for a certain time period at a certain temperature. Therefore, the memory device may have an existing partition closure strategy that indicates to close the partition after a time period since the partition has been opened. However, the memory device may not be operating at the certain temperature for the entire time period. For example, the mean temperature of the drive may be lower than the certain temperature for the at least a portion of the time period. Aspects described herein may enable the processing logic to keep the partition open for a longer time period without experiencing significant SCL. This may reduce unnecessary partition closures and quantities of closed partial blocks under certain host workloads.

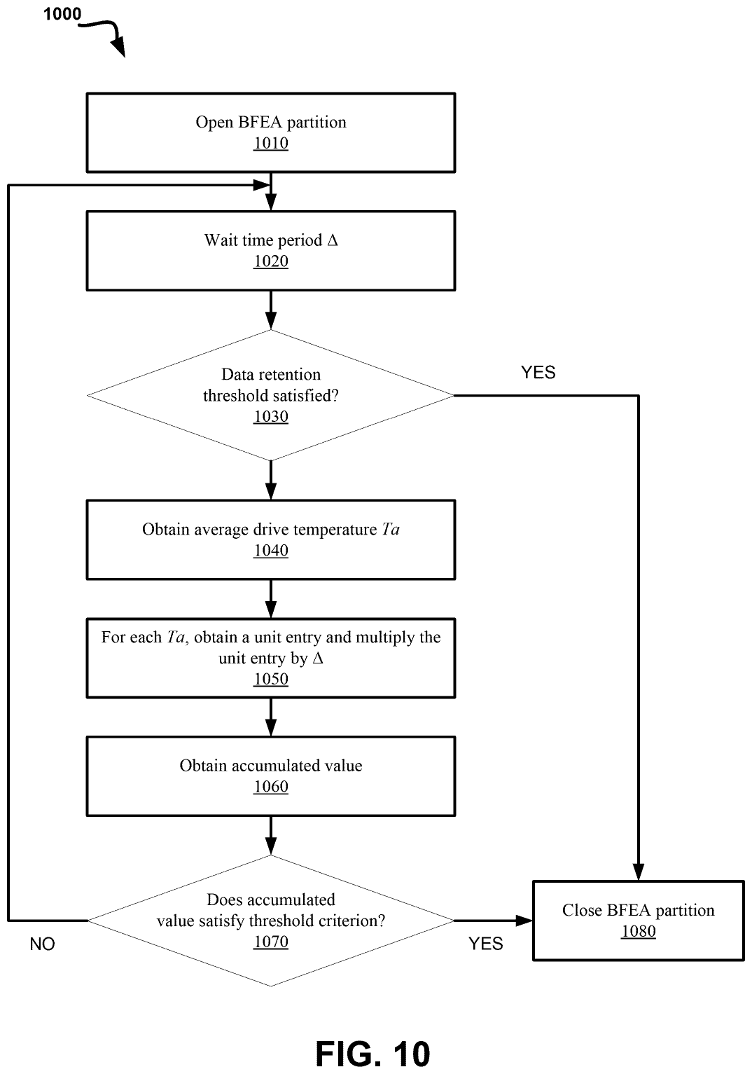

FIG. 10 is a flow diagram of an example method 1000 for block family error avoidance partition management, in accordance with some aspects of the present disclosure. The method 1000 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some aspects, the method 1000 is performed by the partition management component 113 of FIG. 1. Although shown in a particular sequence or order, unless otherwise specified, the order of the processes can be modified. Thus, the illustrated aspects should be understood only as examples, and the illustrated processes can be performed in a different order, and some processes can be performed in parallel. Additionally, one or more processes can be omitted in various aspects. Thus, not all processes are required in every embodiment. Other process flows are possible.

At operation 1010, the processing logic opens a BFEA partition. The processing logic may open the partition in accordance with one or more conditions. For example, the processing logic may open the BFEA partition based on data being written to one or more memory cells of the memory device within a certain time duration (e.g., one hour). The processing logic may determine that data written to the one or more memory cells within the certain time duration is to be treated as a group, and therefore, may logically mark (e.g., tag) the data as being associated with the BFEA partition. In some aspects, data that is included within the same BFEA partition may have the same physical characteristics. For example, data that is included within the same BFEA partition may have the same SCL.

At operation 1020, the processing logic waits a time period Δ. The processing logic may wait the time period Δ after the BFEA partition has been opened. For example, the processing logic may open the BFEA partition and may wait the time period Δ (for example, Δ minutes) before proceeding to operation 1030. In some aspects, the time period Δ may correspond to a time period associated with calculating the average drive temperature.

At operation 1030, the processing logic determines whether a data retention threshold has been satisfied. The data retention threshold may be a time period associated with the BFEA partition being open. If the processing logic determines that the data retention threshold has been satisfied, the processing logic may proceed to operation 1080. For example, if the processing logic determines that the BFEA partition has been open for a time period that is longer than the time period indicated by the data retention threshold, the processing logic may close the BFEA partition. Alternatively, if the processing logic determines that the data retention threshold has not been satisfied, the processing logic may proceed to operation 1040.

At operation 1040, the processing logic obtains an average drive temperature Tₐ. The average drive temperature Tₐ may be an average drive temperature associated with a current time period. For example, the average drive temperature Tₐ may be the average drive temperature of the drive during the time period Δ. The average drive temperature Tₐ may be based on one or more samples of the drive temperature that were obtained during the time period Δ.

At operation 1050, for each average drive temperature Tₐ, the processing logic obtains a unit entry and multiplies the unit entry by Δ. The unit entry may be obtained from a LUT, such as Table 1 shown above. The processing logic may obtain the average drive temperature Tₐ corresponding to the current time period Δ (as described in connection with operation 1040) and may locate a corresponding unit entry from the LUT. The unit entry may be, for example, an equivalent value (α) corresponding to the average drive temperature Tₐ in the LUT. The processing logic may multiply the unit entry by Δ, as described, for example, in connection with operation 930 of FIG. 9.

At operation 1060, the processing logic obtains an accumulated value. The accumulated value may be based on the average drive temperature Tₐ. In some aspects, the processing logic may obtain a unit entry for each average drive temperature Tₐ corresponding to each time period Δ of a plurality of time periods Δ and may add the unit entries together to obtain an accumulated value for the plurality of time periods.

At operation 1070, the processing logic determines whether the accumulated value satisfies a threshold criterion. The processing logic may compare the accumulated value to the threshold criterion to determine whether the accumulated value satisfies the threshold criterion. If the accumulated value satisfies the threshold criterion (for example, if the accumulated value is greater than or equal to the threshold criterion), the processing logic proceeds to operation 1080. If the accumulated value does not satisfy the threshold criterion (for example, if the accumulated value is less than the threshold criterion), the processing logic returns to operation 1020.

At operation 1080, the processing logic closes the BFEA partition. In some aspects, the processing logic may close the BFEA partition using the straightforward approach described in connection with operation 950 of FIG. 9. In some other aspects, the processing logic may close the BFEA partition using the look-ahead approach described in connection with operation 950 of FIG. 9.

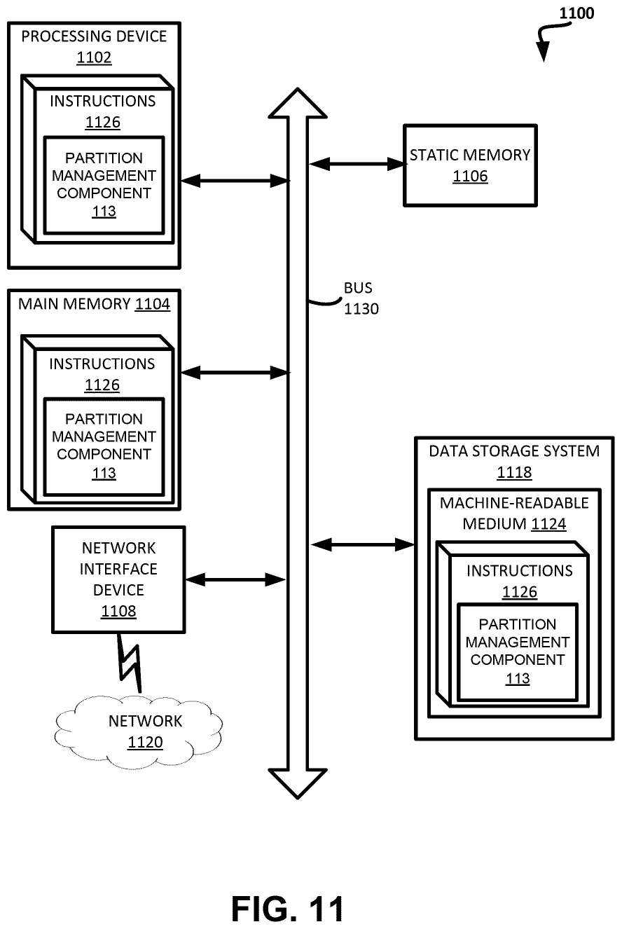

FIG. 11 illustrates an example machine of a computer system 1100 within which a set of instructions, for causing the machine to perform any one or more of the methodologies discussed herein, can be executed. In some aspects, the computer system 1100 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the partition management component 113 of FIG. 1). In alternative aspects, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 1100 includes a processing device 1102, a main memory 1104 (e.g., read-only memory (ROM), flash memory, dynamic random access memory (DRAM) such as synchronous DRAM (SDRAM) or RDRAM, etc.), a static memory 1106 (e.g., flash memory, static random access memory (SRAM), etc.), and a data storage system 1118, which communicate with each other via a bus 1130.

Processing device 1102 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 1102 can also be one or more special-purpose processing devices such as an application specific integrated circuit (ASIC), a field programmable gate array (FPGA), a digital signal processor (DSP), network processor, or the like. The processing device 1102 is configured to execute instructions 1126 for performing the operations and steps discussed herein. The computer system 1100 can further include a network interface device 1108 to communicate over the network 1120.

The data storage system 1118 can include a machine-readable storage medium 1124 (also known as a computer-readable medium) on which is stored one or more sets of instructions 1126 or software embodying any one or more of the methodologies or functions described herein. The instructions 1126 can also reside, completely or at least partially, within the main memory 1104 and/or within the processing device 1102 during execution thereof by the computer system 1100, the main memory 1104 and the processing device 1102 also constituting machine-readable storage media. The machine-readable storage medium 1124, data storage system 1118, and/or main memory 1104 can correspond to the memory sub-system 110 of FIG. 1.

In one embodiment, the instructions 1126 include instructions to implement functionality corresponding to a partition management component (e.g., the partition management component 113 of FIG. 1). While the machine-readable storage medium 1124 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some aspects, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, aspects of the disclosure have been described with reference to specific example aspects thereof. It will be evident that various modifications can be made thereto without departing from the broader spirit and scope of aspects of the disclosure as set forth in the following claims. The specification and drawings are, accordingly, to be regarded in an illustrative sense rather than a restrictive sense.

What is claimed is:

1. A system comprising:
a memory device; and
a processing device, operatively coupled with the memory device, configured to perform operations comprising:
opening a partition comprising a plurality of sets of memory cells;
programming one or more sets of memory cells of the plurality of sets of memory cells;
updating, based on an aggregated drive temperature, an accumulated value that is reflective of one or more physical parameters of the one or more sets of memory cells;
determining whether the accumulated value satisfies a threshold criterion; and
responsive to determining that the accumulated value satisfies the threshold criterion, closing the partition.

2. The system of claim 1, wherein the partition comprises a subset of pages a plurality of pages associated with a superblock.

3. The system of claim 1, wherein the one or more physical parameters include a slow-charge loss (SCL) parameter, and wherein the threshold criterion is an SCL dispersion threshold criterion.

4. The system of claim 1, wherein updating the accumulated value based on the aggregated drive temperature comprises:
obtaining a plurality of drive temperature values;
calculating an average drive temperature value using the plurality of drive temperature values;
calculating an increment value based on the average drive temperature value and a baseline temperature value; and
adding the increment value to the accumulated value.

5. The system of claim 1, wherein the processing device is further configured to perform operations comprising:
determining whether a data retention threshold has been satisfied; and
responsive to determining that the data retention threshold has been satisfied, closing the partition regardless of whether the accumulated value satisfies the threshold criterion.

6. The system of claim 1, wherein determining whether the accumulated value satisfies the threshold criterion comprises comparing the accumulated value and a worst-case predicted value to the threshold criterion.

7. The system of claim 1, wherein the processing device is further configured to perform operations comprising: monitoring a first accumulated value associated with a first die of the partition and a second accumulated value associated with a second die of the partition, wherein determining whether the accumulated value satisfies the threshold criterion comprises determining whether at least one of the first accumulated value or the second accumulated value satisfies the threshold criterion.

8. The system of claim 1, wherein the threshold criterion is determined based on a program erase count (PEC) of the memory device.

9. A method, comprising:
opening, by a processing device, a partition comprising a plurality of sets of memory cells;
programming one or more sets of memory cells of the plurality of sets of memory cells;
updating, based on an aggregated drive temperature, an accumulated value that is reflective of one or more physical parameters of the one or more sets of memory cells;
determining whether the accumulated value satisfies a threshold criterion; and
responsive to determining that the accumulated value satisfies the threshold criterion, closing the partition.

10. The method of claim 9, wherein the partition comprises a subset of pages a plurality of pages associated with a superblock.

11. The method of claim 9, wherein the one or more physical parameters include a slow-charge loss (SCL) parameter, and wherein the threshold criterion is an SCL dispersion threshold criterion.

12. The method of claim 9, wherein updating the accumulated value based on the aggregated drive temperature comprises:
obtaining a plurality of drive temperature values;
calculating an average drive temperature value using the plurality of drive temperature values;
calculating an increment value based on the average drive temperature value and a baseline temperature value; and
adding the increment value to the accumulated value.

13. The method of claim 9, further comprising:
determining whether a data retention threshold has been satisfied; and
responsive to determining that the data retention threshold has been satisfied, closing the partition regardless of whether the accumulated value satisfies the threshold criterion.

14. The method of claim 9, wherein determining whether the accumulated value satisfies the threshold criterion comprises comparing the accumulated value and a worst-case predicted value to the threshold criterion.

15. The method of claim 9, further comprising monitoring a first accumulated value associated with a first die of the partition and a second accumulated value associated with a second die of the partition, wherein determining whether the accumulated value satisfies the threshold criterion comprises determining whether at least one of the first accumulated value or the second accumulated value satisfies the threshold criterion.

16. A non-transitory computer-readable storage medium comprising instructions that, when executed by a processing device, cause the processing device to perform operations comprising:
opening a partition comprising a plurality of sets of memory cells;
programming one or more sets of memory cells of the plurality of sets of memory cells;
updating, based on an aggregated drive temperature, an accumulated value that is reflective of one or more physical parameters of the one or more sets of memory cells;
determining whether the accumulated value satisfies a threshold criterion; and
responsive to determining that the accumulated value satisfies the threshold criterion, closing the partition.

17. The non-transitory computer-readable storage medium of claim 16, wherein the one or more physical parameters include a slow-charge loss (SCL) parameter, and wherein the threshold criterion is an SCL dispersion threshold criterion.

18. The non-transitory computer-readable storage medium of claim 16, wherein the instructions, when executed by the processing device, further cause the processing device to perform operations comprising:
determining whether a data retention threshold has been satisfied; and
responsive to determining that the data retention threshold has been satisfied, closing the partition regardless of whether the accumulated value satisfies the threshold criterion.

19. The non-transitory computer-readable storage medium of claim 16, wherein determining whether the accumulated value satisfies the threshold criterion comprises comparing the accumulated value and a worst-case predicted value to the threshold criterion.

20. The non-transitory computer-readable storage medium of claim 16, wherein the instructions, when executed by the processing device, further cause the processing device to perform operations comprising: monitoring a first accumulated value associated with a first die of the partition and a second accumulated value associated with a second die of the partition, wherein determining whether the accumulated value satisfies the threshold criterion comprises determining whether at least one of the first accumulated value or the second accumulated value satisfies the threshold criterion.
